(19) United States
(12) Patent Application Publication
(10) Pub. No.: US 2017/0084643 A1
(43) Pub. Date: Mar. 23, 2017

(54) Storage Capacitors for Displays and Methods for Forming the Same

(71) Applicant: Intermolecular, Inc., San Jose, CA (US)

(72) Inventors: Gaurav Saraf, San Jose, CA (US); Howard Lin, Santa Clara, CA (US); Prashant Phatak, San Jose, CA (US); Sang Lee, San Jose, CA (US); Minh Huu Le, San Jose, CA (US); Hieu Pham, Santa Clara, CA (US); Congwen Yi, San Jose, CA (US)

(73) Assignee: Intermolecular, Inc., San Jose, CA (US)

(21) Appl. No.: 15/264,822

(22) Filed: Sep. 14, 2016

Related U.S. Application Data
(60) Provisional application No. 62/220,037, filed on Sep. 17, 2015.

(51) Int. Cl. H01L 27/12; H01L 21/02; H01L 21/285; H01L 49/02

(52) U.S. Cl. CPC H01L 27/1255; H01L 27/1259; H01L 28/60; H01L 21/02164; H01L 21/02178; H01L 21/02266; H01L 21/2855; H01L 21/02194; H01L 21/02189; H01L 21/02181; H01L 21/02186

(57) ABSTRACT

Embodiments provided herein describe storage capacitors for active matrix displays and methods for making such capacitors. A substrate is provided. A bottom electrode is formed above the substrate. A dielectric layer is formed above the bottom electrode. A top electrode is formed above the dielectric layer. A layer including an amorphous or crystalline material may be formed between the dielectric layer and the top electrode. The bottom electrode may have a thickness of at least 1000 Å, be formed in a gaseous environment of at least 95% argon, and/or not undergo an annealing process before the formation of a dielectric layer above the bottom electrode. The dielectric layer may include a nitrided high-k dielectric material.

### CROSS-REFERENCE TO RELATED APPLICATIONS

This application claims priority to U.S. Provisional Patent Application Ser. No. 62/220,037 filed on Sep. 17, 2015, which is herein incorporated by reference for all purposes.

### TECHNICAL FIELD

The present invention relates to active matrix displays, such as active matrix liquid crystal displays (AM LCDs) and active matrix organic light emitting diode displays (AM OLEDs). More particularly, this invention relates to storage capacitors for active matrix displays and methods for forming such storage capacitors.

### BACKGROUND

Storage capacitors are critical components for reducing display flicker in active matrix displays, such as liquid crystal displays (AM LCDs) and active matrix organic light emitting diode displays (AM OLEDs). The storage capacitors hold charge during the ON-OFF cycle of the thin-film transistor (TFT) to retain liquid crystal state, and reduce the impact of parasitic gate-drain capacitor. It is desirable for the storage capacitors to have a high capacitance density to sustain charge for a long time period for low frequency operation of the display. Additionally, as LCDs continue to evolve, there is an ever growing need for increased resolution (e.g., from 300 ppi to 700 ppi) and reduced power consumption, particularly in mobile devices. One way to reduce power consumption is by reducing the refresh rate of the pixel or pixel line, which may be accomplished by holding charge in the storage capacitor for longer duration.

Increased capacitance density may be achieved by increasing the dielectric constant and/or reducing the thickness of the insulator used in the capacitor. The use of high dielectric constant insulators (i.e., high-k dielectrics) in the storage capacitors may be helpful in this regard and help to enable such evolution of LCDs.

However, the integration of high-k dielectrics into current LCD technology has been challenging. High-k dielectrics typically require the material to be crystalline with high polarizibility. The crystalline phase of the high-k dielectric material often causes integration issues in the storage capacitor, such as undesirably high leakage density, moisture or chemical instability, surface and interface roughness, top electrode selective etch, etc., which in turn leads to poor capacitance performance.

Other important requirements include extremely low leakage density (e.g., comparable to silicon oxynitride, which is widely used as a dielectric for storage capacitors), high capacitance density, low temperature processing, optical transparency etc. Another issue involves dielectric relaxation observed for high-k dielectrics, which may be either due to bulk dielectric defects or interface relaxation mismatch between the layers (i.e., in multi-layer dielectrics) called the Maxwell-Wagner relaxation. Such relaxation effects cause charge redistribution once the TFT is switched OFF, and can be perceived as flicker.

It is critical to resolve these integration issues, while retaining the high dielectric constant of the storage capacitor.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 is a cross-sectional view of a substrate with a storage capacitor formed above according to some embodiments.

FIG. 2 is a cross-sectional view of a substrate with a storage capacitor formed above according to some embodiments.

FIGS. 3 and 4 are graphs demonstrating the optical responses of liquid crystal displays utilizing storage capacitors according to some embodiments.

FIG. 5 is a cross-sectional view of a substrate with a thin-film transistor and a storage capacitor formed above according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims, and numerous alternatives, modifications, and equivalents are encompassed.

Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g.

sidewall), “higher”, “lower”, “upper”, “over”, and “under”, are defined with respect to the horizontal plane. The term “on” means there is direct contact between the elements. The term “above” will allow for intervening elements.

Embodiments described herein provide storage capacitors for active matrix displays, such as active matrix liquid crystal displays (AM LCDs) and active matrix organic light emitting diode displays (AM OLEDs), and methods for forming storage capacitors for such displays. The storage capacitors described facilitate the use high-k dielectric materials in the storage capacitors and/or improve performance with respect to, for example, display flicker, display resolution, and efficiency.

In some embodiments, a storage capacitor is provided with an amorphous (or micro-crystalline) layer between a high-k dielectric layer and the top (or upper) electrode of the capacitor. For example, the storage capacitor may include a bottom (or lower) electrode made of, for example, indium-tin oxide (ITO). A high-k dielectric layer may be formed above the bottom electrode and be made of, for example, magnesium-zirconium oxide, zirconium oxide, hafnium oxide, or titanium oxide. The amorphous layer may be formed above the high-k dielectric layer and be made of, for example, aluminum oxide, aluminum nitride, or silicon dioxide. The top electrode of the capacitor may be formed above the amorphous dielectric layer and be made of, for example, ITO.

In some embodiments, a storage capacitor is provided with a unique bottom electrode, perhaps but not necessarily, in combination with the amorphous layer described above. For example, the bottom electrode may me made of, for example, ITO and have a thickness (e.g., 1000 Å or more) that is greater than those conventionally used in such storage capacitors and/or the bottom electrode may not be annealed before subsequent processing steps in the formation of the storage capacitor (e.g., the formation of the dielectric layer) so that the bottom electrode remains relatively amorphous (or micro-crystalline), as opposed to crystalline. Additionally, processing parameters (e.g., argon and/or oxygen content in the processing chamber) used in the formation of the bottom electrode may be selected to further enhance the amorphous structure of the bottom electrode. In some embodiments, the substrate on which the storage capacitor is formed includes glass with a layer of acrylic resin formed thereon.

In some embodiments, the storage capacitor is provided with a nitrided dielectric layer (e.g., a nitrided high-k dielectric layer) between the bottom electrode and the top electrode. For example, the dielectric layer may be made of, for example, magnesium-zirconium oxynitride, zirconium oxynitride, hafnium oxynitride, or titanium oxynitride. The dielectric layer may be nitrided during deposition (i.e., in-situ) by, for example, physical vapor deposition (PVD), chemical vapor deposition (CVD), plasma-enhanced CVD (PECVD), atomic layer deposition (ALD) or after deposition (i.e., ex-situ) by, for example, plasma treatments, gas treatments, annealing processes, chemical treatments, etc.

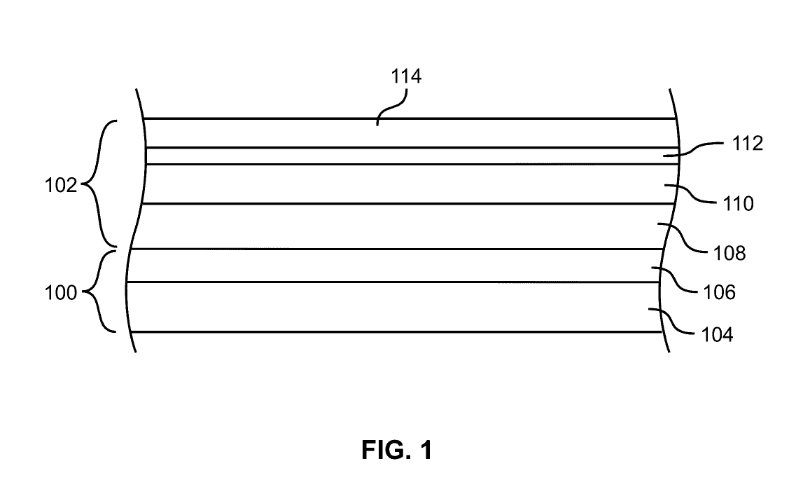

FIG. 1 illustrates a substrate 100 with a storage capacitor 102 formed thereon according to some embodiments. In some embodiments, the substrate 100 includes a glass body (or layer) 104 and a resin (e.g., acrylic resin) layer 106 formed above (i.e., directly on) the glass body 104 (e.g., an “HRC substrate,” as is commonly understood in the art). In some embodiments, an upper surface of the resin layer 106 has a surface roughness of between about 0.25 root mean squared (RMS) nanometers (nm) and 0.6 RMS nm, such as about 0.4 RMS nm, due in part because of the inherent surface roughness of the upper surface of the glass body 104 (e.g., between about 0.1 RMS nm and about 0.3 RMS nm).

The storage capacitor 102 includes multiple components or layers, such as a bottom electrode 108, a dielectric layer 110, an intermediate layer 112, and a top electrode 114.

In some embodiments, the bottom electrode 108 is made of a conductive material, such as a transparent conductive oxide (TCO), a metal, or a metal nitride. For example, in some embodiments, the bottom electrode includes (e.g., is made of) ITO and has a thickness of at least 1000 Å, such as between about 1000 Å and about 1500 Å. The bottom electrode 108 may be formed above the substrate 100 (e.g., directly on the resin layer 106) using, for example, PVD, CVD, PECVD, or ALD.

In some embodiments, the processing step(s) used to form the bottom electrode 108 are optimized to minimize the crystalline structure of the material of the bottom electrode 108 (i.e., such that the bottom electrode is substantially amorphous (or micro-crystalline). For example, in some embodiments, the bottom electrode is formed using PVD in which the gaseous environment is controlled with respect to the concentration of argon and/or oxygen present during the deposition process. As one specific example, the flow of argon in the PVD chamber may be between about 40 standard cubic centimeters per minute (sccm) and about 100 sccm, preferably less than about 50 sccm, and the flow of oxygen in the PVD chamber may be between about 0 sccm and about 2 sccm, preferably less than about 2 sccm. Thus, in some embodiments, the gaseous environment in the PVD chamber may include between about 95% and about 100% argon gas and between about 0% and about 5% oxygen gas by volume.

Additionally, in some embodiments, the bottom electrode 108 (and/or the substrate 100) does not undergo an annealing process after the deposition of the material of the bottom electrode 108, as is typically the case in the formation of such storage capacitors. As a result of the thickness of the bottom electrode 108, the processing parameters used to form the bottom electrode 108, and/or the lack of an annealing process, the upper surface of the bottom electrode is relatively smooth, and the material of the bottom electrode 108 is relatively amorphous.

Still referring to FIG. 1, the dielectric layer 110 is formed above (e.g., directly on) the bottom electrode 108. In some embodiments, the dielectric layer 110 includes (e.g., is made of) a crystalline dielectric material. For example, the first dielectric layer 110 may include a high-k dielectric material, such as magnesium-zirconium oxide, zirconium oxide, hafnium oxide, or titanium oxide, and have a thickness of, for example, between about 500 Å and about 1000 Å, such as about 800 Å. The first dielectric layer 110 may be formed using, for example, PVD, CVD, PECVD, or ALD.

The intermediate (or amorphous or micro-crystalline) layer 112 is formed above (e.g., directly on) the dielectric layer 110. In some embodiments, the intermediate layer 112 includes (e.g., is made of) an amorphous or micro-crystalline material (or a combination thereof) that may be dielectric, semiconducting, or conducting. The material may also have a dielectric constant that is at least 1, be transparent in the visible range of electromagnetic radiation, have a band gap energy (E_{g}) that is less than 3 electron volts (eV), and be deposited using physical (e.g., PVD), chemical, or spin-on methods.

In some embodiments, the intermediate layer 112 includes aluminum oxide, aluminum nitride, or silicon dioxide and has a thickness of, for example, between about 50 Å and about 200 Å, such as about 100 Å. The intermediate layer 112 may be formed using, for example, PVD, CVD, PECVD, or ALD.

The top electrode 114 is formed above (e.g., directly on) the intermediate layer 112. In some embodiments, the top electrode 114 is made of the same material as the bottom electrode 108 (e.g., ITO) and formed using the same type of processing (e.g., PVD). The top electrode may have a thickness of, for example, between about 400 Å and about 800 Å, such as about 500 Å.

The inclusion of the amorphous or micro-crystalline material of the intermediate layer 112 may in effect “break” (or interrupt) the crystallinity of the material(s) of the dielectric layer 110. As a result, the material of the top electrode 114 may form in such a way that it is less crystalline (or more amorphous) than is the case when the top electrode 114 is formed directly on the relatively crystalline material(s) of the dielectric layer 114. This facilitates the patterning and etching of the top electrode 114 with sufficient selectivity to the material of the dielectric layer 110. For example, the likelihood that voids will be formed at the bottom of the dielectric layer 110 and/or the storage capacitor 102 will peel off of the substrate 100 as a result of an etching process may be reduced.

Additionally, the formation of columnar structures in the top electrode 114 may be reduced, which improves surface planarization and reduces roughness at both the top surface of the top electrode 114 and at the interface of the top electrode 114 and the amorphous layer 112. The intermediate layer 112 may also improve (i.e., increase) the dielectric breakdown field (EBD), protect the high-k dielectric from moisture, water, and other chemical interaction during subsequent processing steps, act as leakage blocking layer, and lower leakage density.

The increased thickness of the bottom electrode 108, as well as not annealing the bottom electrode 108, may improve the planarization and/or reduce the surface roughness of the bottom electrode, which in turn may improve the planarization/reduce the surface roughness of the components formed thereon, particularly when the intermediate layer 112 is utilized. For example, the interface between the bottom electrode 108 and the dielectric(s) formed thereon may be smoothed, as may the interface between the dielectric layer 110 and the intermediate layer 112 and the top surface of the top electrode 114. In one experiment, the surface roughness of the top electrode 114, when formed above an HRC substrate with the relatively thick, amorphous bottom electrode 108 and the intermediate layer 112, was about 1.77 RMS nm. In contrast, when a conventional bottom electrode and no amorphous layer was used on an HRC substrate, the surface roughness of the top electrode 114 was 4.12 RMS nm. These improved, relative smooth interfaces may result in decreased leakage density for the storage capacitor 102. As a result, the performance of the storage capacitor 102, particularly when formed on HRC substrates, may be improved.

Additionally, these relatively smooth interfaces may allow for the integration of the high-k dielectric materials described above (e.g., in the dielectric layer 110), particularly on HRC substrates, enabling increased capacitance density, along with a reduced total capacitor thickness and power consumption and further reduced leakage density.

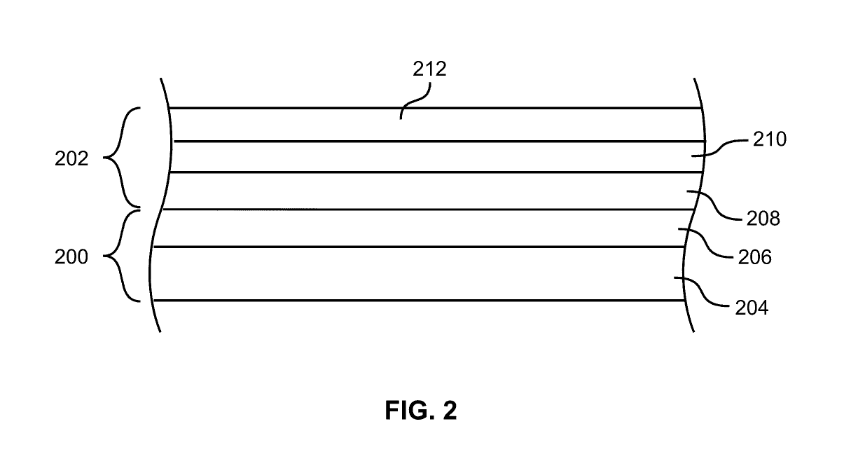

FIG. 2 illustrates a substrate 200 with a storage capacitor 202 formed thereon according to some embodiments. In some embodiments, the substrate 200 includes a glass body (or layer) 204 and an acrylic resin layer 206 formed above (i.e., directly on) the glass body 204.

The storage capacitor 202 includes multiple components or layers, such as a bottom electrode 208, a dielectric layer (or a dielectric layer stack) 210, and a top electrode 212. In some embodiments, the bottom electrode 208 is made of a conductive material, such as a transparent conductive oxide (TCO), a metal, or a metal nitride. For example, in some embodiments, the bottom electrode 208 includes (e.g., is made of) ITO and has a thickness of, for example, between about 400 Å and about 800 Å, such as about 500 Å. The bottom electrode 208 may be formed above the substrate 100 (e.g., directly on the resin layer 106) using, for example, PVD, CVD, PECVD, or ALD.

Still referring to FIG. 2, the dielectric layer 210 is formed above (e.g., directly on) the bottom electrode 208. In some embodiments, the dielectric layer 210 includes (e.g., is made of) a nitrided high-k dielectric material with a dielectric constant (k) greater than 7, such as magnesium-zirconium oxynitride, zirconium oxynitride, hafnium oxynitride, titanium oxynitride, or a combination thereof. The atomic concentration of nitrogen in the nitrided high-k dielectric material may be at least 0.1%.

The dielectric layer 210 may have a thickness of, for example, between about 500 Å and about 1000 Å, such as about 800 Å. The dielectric layer 210 may be formed using, for example, PVD, CVD, PECVD, or ALD. In some embodiments, the nitridation of the dielectric layer 210 is performed during the deposition process (i.e., in-situ). For example, the nitridation may be achieved by introducing nitrogen gas into the processing chamber during a PVD process used to form the dielectric layer 210. In some embodiments, the nitridation of the dielectric layer is formed after the deposition process (i.e., ex-situ), such as after the deposition process, using, for example, plasma treatments (e.g., remote plasma or direct plasma, such as nitrogen, ammonia, etc), gas treatments, annealing processes (e.g., in a gaseous environment including elemental or molecular nitrogen), chemical treatments, etc. Although not shown in FIG. 2, in some embodiments, the dielectric layer 210 is formed by multiple layers (i.e., a dielectric layer stack) such as a first dielectric layer made of, for example, the nitrided high-k dielectric(s) described above and a second dielectric layer (formed above/on the first dielectric layer) made of, for example, the amorphous (or micro-crystalline) dielectric(s) described with respect to FIG. 1 (e.g., a 100 Å layer of aluminum oxide).

The top electrode 212 is formed above (e.g., directly on) the dielectric layer 210. In some embodiments, the top electrode 212 is made of the same material as the bottom electrode 208 (e.g., ITO) and formed using the same type of processing (e.g., PVD). The top electrode 212 may have a thickness of, for example, between about 400 Å and about 800 Å, such as about 500 Å.

The nitridation of the high-k dielectric material in the dielectric layer 210 may passivate charged oxygen vacancies in the bulk of the dielectric and also passivate interface defects/traps. This may result in reduced flicker and/or transient behavior due to dielectric relaxation, which in turn may reduce the polarization redistribution once the applied bias (TFT in this case) is removed.

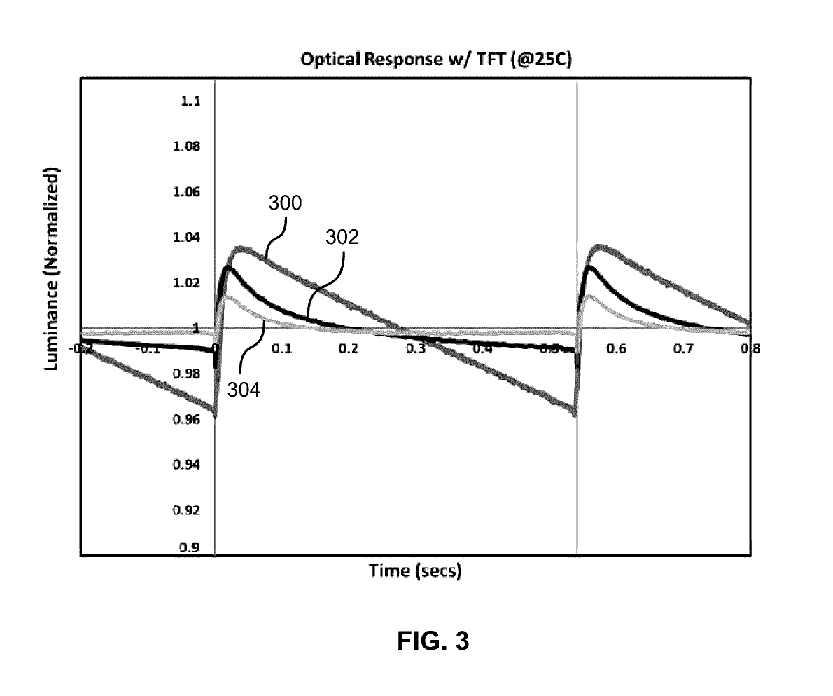

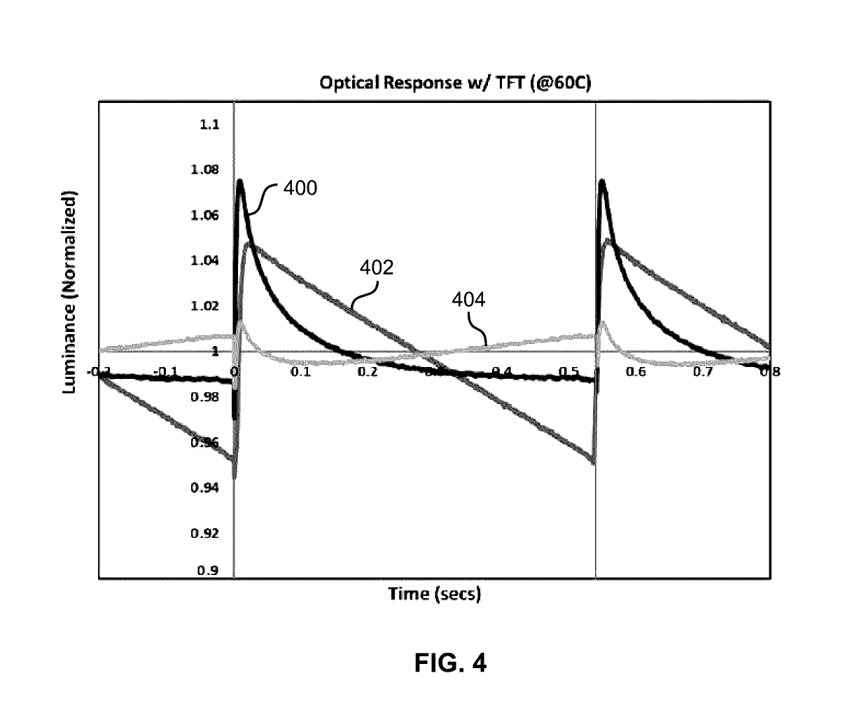

FIGS. 3 and 4 illustrate the flicker of several liquid crystal displays utilizing various storage capacitors at 25° C. and 60° C., respectively. Line 300 in FIG. 3 and line 400 in FIG. 4 correspond to a storage capacitor utilizing a silicon oxynitride dielectric layer. Line 302 in FIG. 3 and line 402 in FIG. 4 correspond to a storage capacitor utilizing a dielectric layer stack including an aluminum oxide layer formed over a magnesium-zirconium oxide (MgZrOₓ) layer. Line 304 in FIG. 3 and line 404 in FIG. 4 correspond to a storage capacitor utilizing a dielectric layer stack including an aluminum oxide layer formed over a magnesium-zirconium oxynitride (MgZrOₓN_{y}) that was nitrided in-situ during deposition (i.e., via PVD in a gaseous environment of 25% nitrogen gas). As shown, the storage capacitor utilizing the nitrided magnesium-zirconium oxide (lines 304 and 404) demonstrated significant improvement (i.e., reduction) in LC flicker (or optical response) at both 25° C. and 60° C., particular when compared to the storage capacitor utilizing silicon oxynitride (lines 300 and 400).

In another example, high-k dielectric magnesium-zirconium oxide (MgZrOₓ) was nitrided in-situ during deposition (e.g., via PVD in a gaseous environment of 50% nitrogen gas) to form magnesium-zirconium oxynitride (MgZrOₓN_{y}). The nitrided high-k dielectric exhibited reduced surface (and/or interface) roughness and columnar structure (i.e., a more amorphous/micro-crystalline structure) and refractive index, as well as reduced texture and bulk defects. The resulting storage capacitor demonstrated significant improvement (i.e., reduction) in leakage density, relaxation current, and LC flicker without deterioration of capacitance density/dielectric constant or equivalent nitride thickness (ENT).

The nitridation of the high-k dielectric may also help with interface improvement and/or overall integration by reducing the surface or interface roughness with electrodes or other dielectric layers, which in turn may further improve LC display performance.

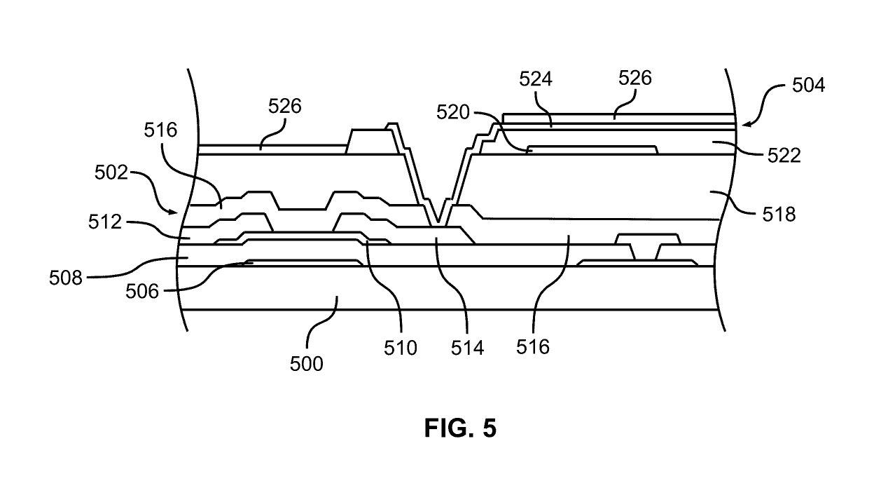

FIG. 5 illustrates a substrate 500 with a thin-film transistor (TFT) 502 and a storage capacitor 504 formed thereon according to some embodiments. In some embodiments, the substrate 500 is transparent and is made of, for example, glass. The substrate 500 may have a thickness of, for example, between 0.01 and 0.5 centimeters (cm). Although only a portion of the substrate 500 is shown, it should be understood that the substrate 500 may have a width of, for example, between 5.0 cm and 4.0 meters (m). Although not shown, in some embodiments, the substrate 502 may have a dielectric layer (e.g., silicon oxide) formed above an upper surface thereof. In such embodiments, the components described below are formed above the dielectric layer.

With respect to the TFT 502 (e.g., inverted, staggered bottom-gate TFT), a gate electrode 506 is formed above the transparent substrate 500. In some embodiments, the gate electrode 506 is made of a conductive material, such as copper, silver, aluminum, manganese, molybdenum, or a combination thereof. The gate electrode 506 may have a thickness of, for example, between about 200 Å and about 5000 Å. Although not shown, it should be understood that in some embodiments, a seed layer (e.g., a copper alloy) is formed between the substrate 500 and the gate electrode 506.

It should be understood that the various components of the TFT 502 and the storage capacitor 504, such as the gate electrode 506 and those described below, are formed using processing techniques suitable for the particular materials being deposited, such as those described above (e.g., PVD, CVD, electroplating, etc). Furthermore, it should be understood that the various components on the substrate 500, such as the gate electrode 506, may be sized and shaped using a photolithography process and an etching process, as is commonly understood, such that the components are formed above selected regions of the substrate 500.

Still Referring to FIG. 5, a gate dielectric layer 508 is formed above the gate electrode 506 and the exposed portions of the substrate 500. The gate dielectric layer 508 may be made of, for example, silicon oxide, silicon nitride, or a high-k dielectric (e.g., having a dielectric constant greater than 3.9), such as zirconium oxide, hafnium oxide, or aluminum oxide. In some embodiments, the gate dielectric layer 508 has a thickness of, for example, between about 100 Å and about 5000 Å.

A channel layer (or active layer) 510 is formed above the gate dielectric layer 508, over the gate electrode 506. The channel layer 510 may include (e.g., be made of), for example, amorphous silicon, polycrystalline silicon, or indium-gallium-zinc oxide (IGZO). The channel layer 510 may have a thickness of, for example, between about 100 Å and about 1000 Å.

A source region (or electrode) 512 and a drain region (or electrode) 514 are formed above the channel layer 510. As shown, the source region 512 and the drain region 514 lie on opposing sides of, and partially overlap the ends of, the channel layer 510. In some embodiments, the source region 512 and the drain region 514 are made of titanium, molybdenum, copper, copper-manganese alloy, or a combination thereof. The source region 512 and the drain region 514 may have a thickness of, for example, between about 200 Å and 5000 Å.

A passivation layer 516 is formed above the channel layer 510, the source region 512, the drain region 514, and the gate dielectric layer 508. In some embodiments, the passivation layer 516 is made of silicon oxide, silicon nitride, aluminum oxide, aluminum nitride, or a combination thereof and has a thickness of, for example, between about 1000 Å and about 1500 Å.

A resin layer 518 is formed above the passivation layer 516. In some embodiments, the resin layer 518 includes (e.g., is made of) an acrylic resin and may have a thickness of, for example, between about 1000 Å and about 1500 Å.

The storage capacitor 504 is formed above the resin layer 518 and includes a bottom electrode 520, a dielectric layer (or dielectric layer stack) 522, and a top electrode 524, which may be similar to electrodes and dielectric layers (or dielectric layer stacks) described above. In the embodiment depicted in FIG. 5, the top electrode 524 extends into a via (or trench) formed through the resin layer 518 and the passivation layer 516 and in electrically connected to the drain region 514.

Still referring to FIG. 5, an alignment film 526 is formed above the storage capacitor 504 and the portion of the resin layer 518 above the TFT 502. The alignment film may, for example, include (e.g., be made of) polyimide and/or carbon and have a thickness of between about 3 Å and about 1000 Å.

Thus, in some embodiments, storage capacitors for active matrix displays, and methods for forming such storage capacitors, are provided. A substrate is provided. A bottom electrode is formed above the substrate. A dielectric layer is formed above the bottom electrode. The dielectric layer includes a high-k dielectric material. An intermediate layer is formed above the dielectric layer. The intermediate layer includes an amorphous or micro-crystalline material. A top electrode is formed above the intermediate layer.

In some embodiments, storage capacitors for active matrix displays, and methods for forming such storage capacitors, are provided. A substrate is provided. A bottom electrode is formed above the substrate. The bottom electrode may have a thickness of at least 1000 Å, be formed in a gaseous environment of at least 95% argon, not undergo an annealing process before the formation of a dielectric layer above the bottom electrode, or a combination thereof. A dielectric layer is formed above the bottom electrode. A top electrode is formed above the dielectric layer.

In some embodiments, storage capacitors for active matrix displays, and methods for forming such storage capacitors, are provided. A substrate is provided. A bottom electrode is formed above the substrate. A dielectric layer is formed above the bottom electrode. The dielectric layer comprises a nitrided high-k dielectric material. A top electrode is formed above the dielectric layer.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A method for forming a storage capacitor for an active matrix display, the method comprising:
providing a substrate;
forming a bottom electrode above the substrate;
forming a dielectric layer above the dielectric layer, wherein the dielectric layer comprises a high-k dielectric material;
forming an intermediate layer above the dielectric layer, wherein the intermediate layer comprises an amorphous or micro-crystalline material; and
forming a top electrode above the intermediate layer.

2. The method of claim 1, wherein the intermediate layer comprises at least one of aluminum oxide, aluminum nitride, silicon dioxide, or a combination thereof.

3. The method of claim 2, wherein the intermediate layer has a thickness of between about 50 Å and about 200 Å.

4. The method of claim 3, wherein the intermediate layer is formed directly on the dielectric layer.

5. The method of claim 4, wherein the dielectric layer comprises at least one of magnesium-zirconium oxide, zirconium oxide, hafnium oxide, titanium oxide, or a combination thereof.

6. The method of claim 5, wherein the top electrode is formed directly on the intermediate layer.

7. The method of claim 6, wherein the top electrode comprises indium-tin oxide.

8. A method for forming a storage capacitor for an active matrix display, the method comprising:
providing a substrate;
forming a bottom electrode above the substrate;
forming a dielectric layer above the bottom electrode, wherein the dielectric layer comprises a nitrided high-k dielectric material; and
forming a top electrode above the dielectric layer.

9. The method of claim 8, wherein the nitrided high-k dielectric material comprises at least one of magnesium-zirconium oxynitride, zirconium oxynitride, hafnium oxynitride, titanium oxynitride, or a combination thereof.

10. The method of claim 9, wherein the dielectric layer has a thickness of between about 500 Å and about 1000 Å.

11. The method of claim 10, wherein the dielectric layer is formed directly on the bottom electrode, and wherein the top electrode is formed directly on the dielectric layer.

12. The method of claim 11, wherein each of the bottom electrode and the top electrode comprises indium-tin oxide.

13. The method of claim 9, wherein the dielectric layer is formed using a physical vapor deposition (PVD) process in a gaseous environment comprising nitrogen gas.

14. A method for forming a storage capacitor for an active matrix display, the method comprising:
providing a substrate;
forming a bottom electrode above the substrate;
forming a dielectric layer above the bottom electrode; and
forming a top electrode above the dielectric layer,
wherein the bottom electrode comprises indium-tin oxide and has a thickness of at least 1000 Å, is formed in a gaseous environment comprising at least 95% argon gas, does not undergo an annealing process before the forming of the dielectric layer, or a combination thereof.

15. The method of claim 14, further comprising forming an intermediate layer between the dielectric layer and the top electrode, wherein the intermediate layer comprises an amorphous or micro-crystalline material.

16. The method of claim 15, wherein the intermediate layer comprises at least one of aluminum oxide, aluminum nitride, silicon dioxide, or a combination thereof.

17. The method of claim 14, wherein the bottom electrode has a thickness of between about 1000 Å and about 1500 Å.

18. The method of claim 14, wherein the top electrode comprises indium-tin oxide and has a thickness of between about 400 A and about 800 Å.

19. The method of claim 14, wherein the bottom electrode is formed using a physical vapor deposition (PVD) process in a gaseous environment comprising between about 95% and about 100% argon gas and between about 0% and about 5% oxygen gas.

20. The method of claim 14, wherein the dielectric layer comprises at least one of magnesium-zirconium oxide, zirconium oxide, hafnium oxide, titanium oxide, or a combination thereof.
